(19) United States
(12) Patent Application Publication
(10) Pub. No.: US 2017/0373635 A1
(43) Pub. Date: Dec. 28, 2017

(54) PHOTOVOLTAIC SYSTEMS COMPRISING DOCKING ASSEMBLIES

(71) Applicant: SUNPOWER CORPORATION, San Jose, CA (US)

(72) Inventors: Julian Perez, Elgin, TX (US); Phillip Charles Gilchrist, Austin, TX (US)

(21) Appl. No.: 15/192,754

(22) Filed: Jun. 24, 2016

(51) Int. Cl. H02S 40/34; H02S 30/10; H01L 31/044; H01L 31/049; H01L 31/02; H02S 40/32

(52) U.S. Cl. CPC H02S 40/34; H01L 31/0201; H02S 40/32; H01L 31/044; H01L 31/049; H02S 30/10

(57) ABSTRACT

Photovoltaic (PV) assemblies and modules comprising electronic component docking assemblies are described herein. Docking assemblies can comprise a junction box and an electronic component housing configured to be reversibly connected or “docked.” The photovoltaic assemblies and modules described herein facilitate field replacement or removal of electronic components e.g. microinverters from a corresponding module and/or junction box. Additionally, the photovoltaic docking assemblies described herein enable PV modules and arrays with minimal cables and wiring for electrical interconnection.

### BACKGROUND

Typical photovoltaic (PV) modules may generate direct current (DC) power based on received solar energy. PV modules may include a plurality of solar or PV cells electrically coupled to one another allowing the PV cells to contribute to a combined output power for a PV module. A typical PV module generally includes a rectangular frame surrounding a PV laminate encapsulating solar cells, and a junction box. The junction box encapsulates electrical connections protruding from a backsheet of the PV laminate which are in electrical connection with the solar cells of the PV module. In many cases, the junction box is glued to the backsheet of the PV laminate.

In particular applications, the DC power generated by a photovoltaic module may be converted to AC power through the use of a power inverter. The power inverter may be electrically coupled to an output of the PV module. Typically, intervening wiring (e.g. Multi-contact MC4 connectors) may be used between the PV module, junction box and the power inverter. The power inverter may be electrically coupled to the DC output of the PV module (i.e., the PV cables). The power inverter may be located physically apart from the PV module, with only the intervening wiring and associated hardware physically coupling the PV module to the power inverter.

### BRIEF DESCRIPTION OF THE DRAWINGS

The following drawings illustrate by way of example and not limitation. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers. The figures are not drawn to scale.

FIG. 1 depicts a front side of a photovoltaic module, in accordance with an embodiment of the present disclosure;

FIG. 2 depicts a back side of a photovoltaic module, in accordance with an embodiment of the present disclosure;

FIG. 3 depicts a magnified view of a photovoltaic docking assembly, in accordance with an embodiment of the present disclosure;

FIG. 4 depicts a cross-sectional view of a photovoltaic docking assembly, in accordance with an embodiment of the present disclosure;

FIG. 5 depicts a junction box, in accordance with an embodiment of the present disclosure;

FIG. 6 depicts an electronic component, in accordance with an embodiment of the present disclosure.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Certain terminology may be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “axial”, and “lateral” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

Terminology—The following paragraphs provide definitions and/or context for terms found in this disclosure (including the appended claims):

This specification includes references to “one embodiment” or “an embodiment.” The appearances of the phrases “in one embodiment” or “in an embodiment” do not necessarily refer to the same embodiment. Particular features, structures, or characteristics can be combined in any suitable manner consistent with this disclosure.

This term “comprising” is open-ended. As used in the appended claims, this term does not foreclose additional structure or steps.

Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

As used herein, the terms “first,” “second,” etc. are used as labels for nouns that they precede, and do not imply any type of ordering (e.g., spatial, temporal, logical, etc.). For example, reference to a “first” encapsulant layer does not necessarily imply that this encapsulant layer is the first encapsulant layer in a sequence; instead the term “first” is used to differentiate this encapsulant from another encapsulant (e.g., a “second” encapsulant).

The terms “a” and “an” are defined as one or more unless this disclosure explicitly requires otherwise.

The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

As used herein, “inhibit” is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

As used herein, the term “substantially” is defined as largely but not necessarily wholly what is specified (and includes what is specified; e.g., substantially 90 degrees includes 90 degrees and substantially parallel includes parallel), as understood by a person of ordinary skill in the art. In any disclosed embodiment, the terms “substantially,” “approximately,” and “about” may be substituted with “within [a percentage] of” what is specified, where the percentage includes 0.1, 1, 5, and 10 percent.

As used herein, “regions” can be used to describe discrete areas, volumes, divisions or locations of an object or material having definable characteristics but not always fixed boundaries.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present invention. The feature or features of one embodiment can be applied to other embodiments, even though not described or illustrated, unless expressly prohibited by this disclosure or the nature of the embodiments.

Photovoltaic (PV) assemblies and modules for converting solar radiation to electrical energy are disclosed herein. PV arrays comprising a plurality of PV assemblies or PV modules are also described herein. A PV module can comprise a plurality of PV or solar cells encapsulated within a PV laminate. The PV module can further comprise a junction box or housing for enabling or providing electrical access to the plurality of solar cells. The junction box can comprise a plurality of busbars or conductor ribbons electrically coupled to the plurality of solar cells. The junction box can further comprise a direct current (DC) output connector port for outputting direct current generated by the plurality of solar cells, a conditioned power input connector port for receiving conditioned power; and, a conditioned power output link for outputting conditioned power to an external load. The PV module can further comprise an electronic component housing configured to be removably coupled to the junction housing. The electronic component housing can comprise an electronic component and/or circuitry for conditioning power generated by the plurality of solar cells. The electronic component housing can further comprise a DC input connector port configured to be electrically mated with the DC output connector port of the junction housing; and, a conditioned power output connector port configured to be electrically mated with the power input connector port of the junction housing.

Additionally, alternating current photovoltaic (ACPV) assemblies and modules are described herein. An ACPV module can comprise a plurality of PV or solar cells encapsulated within a PV laminate. The ACPV module can further comprise a junction box or housing for enabling or providing electrical access to the plurality of solar cells. The junction box can comprise a plurality of busbars or conductor ribbons electrically coupled to the plurality of solar cells. The junction housing can comprise a direct current (DC) output connector port for outputting direct current generated by the plurality of solar cells, an alternating current (AC) input connector port for receiving AC power; and, an alternating current (AC) output link or cable for outputting AC power to an external load. The ACPV module can further comprise a power inverter or DC-AC inverter, commonly referred to as a “microinverter,” for converting direct current to alternating current. The microinverter is configured to be removably coupled to the junction box. The microinverter can comprise a housing with a DC input connector port configured to be electrically mated with the DC output connector port of the junction box and an AC output connector port configured to be electrically mated with the AC input connector port of the junction box. The microinverter can convert direct current generated by the plurality of solar cells to alternating current for delivery to an external AC load via the AC output cable of the junction housing.

Photovoltaic docking assemblies are also described herein. A photovoltaic docking assembly comprises a junction box or housing and an electronic component housing configured to be reversibly connected or “docked.” The photovoltaic docking assembly can comprise a junction box comprising a plurality of busbars or conductor ribbons electrically coupled to a plurality of solar cells. The junction housing can further comprise a DC output connector port for outputting direct current generated by the plurality of solar cells, a conditioned power input connector port for receiving conditioned power; and, a conditioned power output link or cable for outputting conditioned power for an external load. The photovoltaic docking assembly further comprises an electronic component for conditioning power generated by the plurality of solar cells. The electronic component housing can comprise a DC input connector port configured to be electrically mated with the DC output connector port of the junction housing; and, a conditioned power output connector port configured to be electrically mated with the power input connector port of the junction housing.

Repair and/or replacement of electronic components of PV assemblies and modules e.g. microinverters of ACPV modules can be challenging. For example, if a microinverter of an ACPV module fails, it may be difficult or impossible to replace just the microinverter, causing the loss of both the microinverter and the PV module. Further, grounding of the microinverter and PV module may pose additional challenges. Various embodiments of both PV and ACPV modules to address these challenges are described herein. The photovoltaic docking assemblies described herein facilitate field replacement or removal of electronic components e.g. microinverters from a corresponding module and/or junction box. Additionally, the photovoltaic docking assemblies described herein enable PV modules and arrays to have minimal cables and wiring for electrical interconnection.

Although many of the examples described herein are alternating current photovoltaic (ACPV) modules, the techniques and structures apply equally to other (e.g., direct current) PV modules as well.

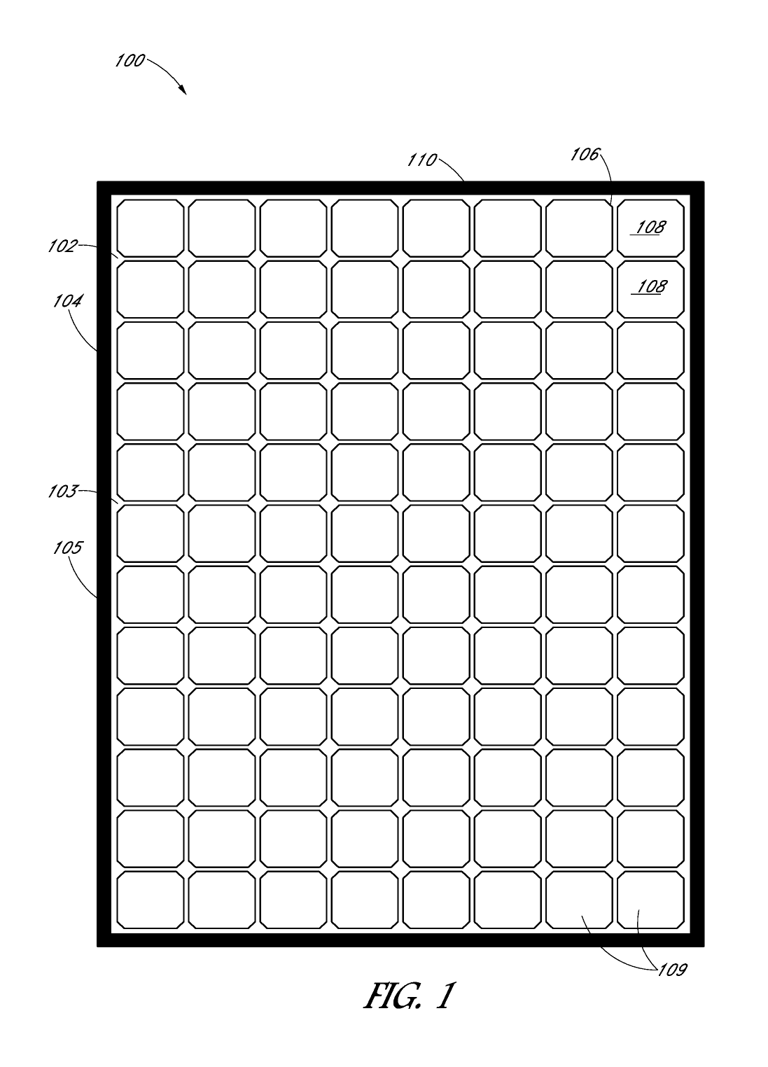

FIG. 1 illustrates top-down view of a module 100 having a front side 102 that faces the sun during normal operation and a back side 104 opposite the from side 102. In some embodiments, the module 100 can comprise a laminate 106 containing a plurality of solar cells 108 and a frame 110 surrounding the laminate 106. The solar cells 108 can face the front side 102 and be arranged into a plurality of solar cell strings 109. The laminate 106 can include one or more encapsulating layers which surround and enclose the solar cells 108. In various embodiments, the laminate 106 comprises a top cover 103 made of glass or another transparent material on the front side 102. In certain embodiments, the material chosen for construction of the cover 103 can be selected for properties which minimize reflection, thereby permitting the maximum amount of sunlight to reach the solar cells 108. The top cover 103 can provide structural rigidity to the laminate 106. The laminate 106 can further comprise a backsheet 105 on the back side 104. The backsheet 105 can be a weatherproof and electrically insulating layer which protects the underside of the laminate 106. The backsheet 105 can be a polymer sheet, and it can be laminated to encapsulant layer(s) of the laminate 106, or it can be integral with one of the layers of the encapsulant.

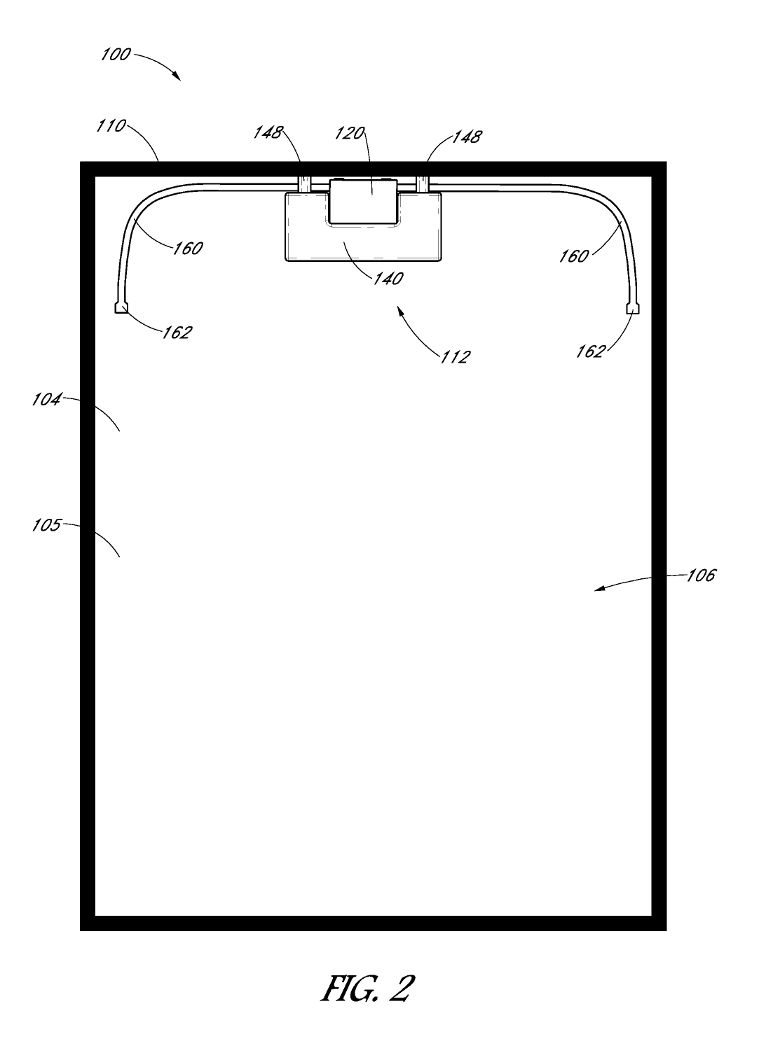

FIG. 2 depicts a view of the back side 104 of module 100 comprising a docking assembly 112. The docking assembly 112 comprises a junction box or housing 120 for providing electrical access to the plurality of solar cells 108 encapsulated within the laminate 106. In an embodiment, the junction box or housing 120 is coupled to the backsheet 105 of the laminate 106 via an adhesive or other securing device or feature. In some embodiments, the junction box or housing 120 can be coupled to the frame 110 via screws, an adhesive or other securing device or feature. The junction box or housing 120 comprises conditioned power output links or cables 160 extending therefrom. The conditioned power output cables 160 output conditioned power to an external load (not pictured). The conditioned power output cables 160 comprise conditioned power output connectors 162 which can be connected directly to an external load and/or to adjacent modules to form a photovoltaic array.

As depicted in FIG. 2, the back side 104 of the module 100 further comprises an electronic component 140 for conditioning power generated by the solar cells 108. The electronic component 140 is configured to be removably coupled to the junction box or housing 120. The electronic component 140 can be both electrically and mechanically coupled to the junction box 120. In several embodiments, the electronic component can comprise a microinverter for converting direct current generated by the solar cells 108 to alternating current or AC power. In such embodiments, the module 100 can be described as an ACPV module.

In some embodiments, the electronic component 140 is mounted to the frame 110 of the module 100. The electronic component 140 can comprise mating features for mechanically coupling to a corresponding mating feature of the frame 110. For example as depicted in FIG. 2, the electronic component 140 comprises mounting arms 148 configured to be removably coupled to the frame 110 of the module 100 as will be described in further detail below.

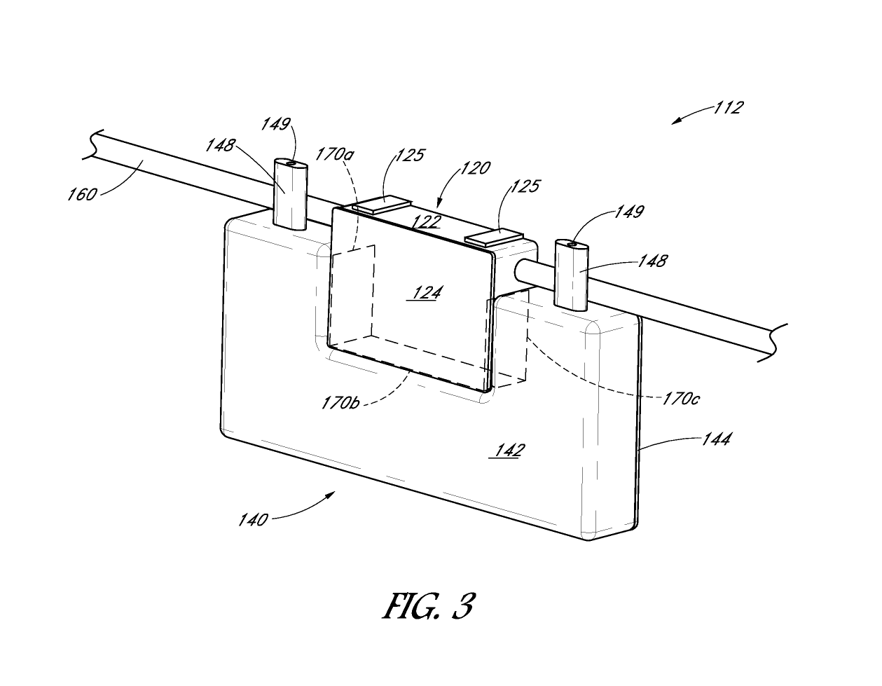

FIG. 3 depicts a magnified view of photovoltaic docking assembly 112 in a docked state. The junction box 120 Comprises a housing or enclosure 122 with a cover 124. The junction enclosure 122/124 seals the junction box 120 from moisture, dust and other contaminants, and also dissipates heat that is generated by components inside the junction box. The junction enclosure 122/124 can be integrally formed or be formed from an assembly of parts. The junction enclosure 122/124 can comprise mating features for mating or coupling to the laminate 106 or frame 110. For example as depicted in FIG. 3, the junction box 120 comprises leveling features 125 for contacting frame 110 in a level or supported manner. The junction enclosure 122/124 can be formed from any desirable material, for example an electrically insulating polymeric material like ABS. A conductive material may be used for the junction enclosure, but additional measures may be needed to provide electrical isolation from other components.

The electronic component 140 comprises a housing or enclosure 142 with a cover 144. The electronic component housing 142/144 can be integrally formed or be formed from an assembly of parts. In an embodiment, the electronic component housing 142/144 is composed of a metallic material such as aluminum. In another embodiment, the electronic component housing 142/144 is composed of a heat dissipating polymer. The electronic component housing 142 and cover 144 seal the junction electrical component 140 from moisture, dust and other contaminants, and also dissipates heat that is generated by interior components.

In the embodiment depicted in FIG. 3, the electronic component 140 is docked to the junction box 120 such that the electronic component 140 partially surrounds the junction box 120 and makes contact at three interfacial contact planes generally indicated at 170a-c. However, the electronic component 140 can be docked to the junction box 120 in any desirable configuration. For example, in another embodiment, the electronic component 140 can be docked to the junction box 120 in an adjacent or bordering configuration such that a single interfacial contact plane exists between the electronic component and the junction box. For example, the electronic component 140 can be docked to the junction box at the junction box cover 124. In yet other embodiments, the electronic component 140 can be docked to the junction box 120 such that the electronic component 140 substantially entirely surrounds the junction box 120. Any desired number of interfacial contact planes can be provided between the electronic component and the junction box in a docked state. In an embodiment, the docking configuration of the electronic component relative to the junction box is dictated by the ease of accessibility for removal or replacement of the electronic component (e.g. facilitating removal or replacement of a microinverter from an ACPV module).

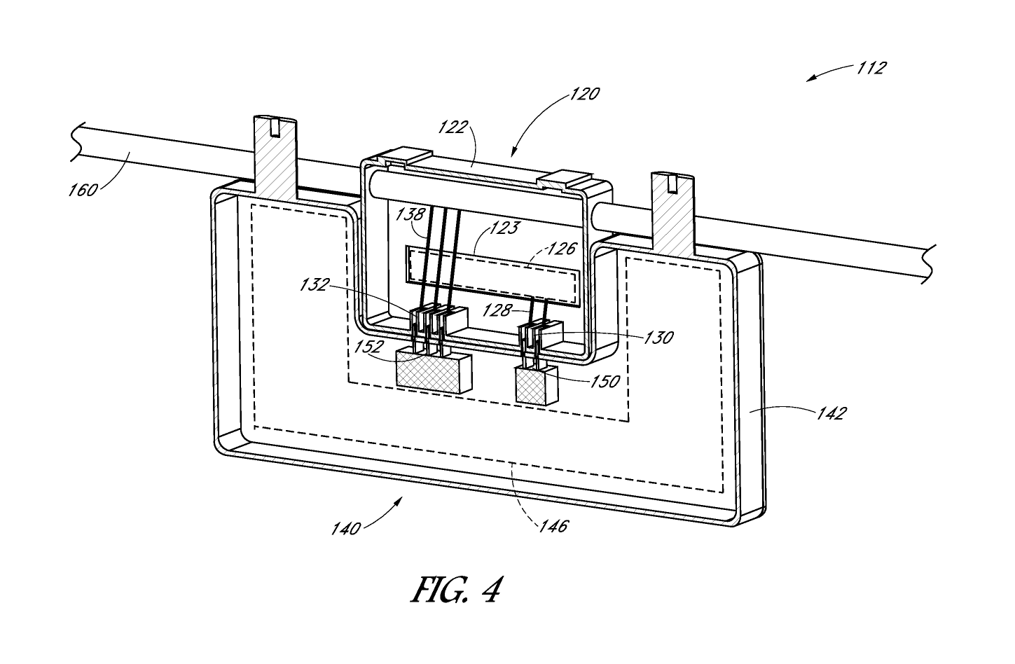

FIG. 4 depicts a cross-sectional view of photovoltaic docking assembly 112. In an embodiment, the junction box 120 can comprise a simple circuit board to provide wire connections and bypass diodes. In FIG. 4, the junction box 120 houses a simplistic, passive connection or junction circuit generally indicated by a dashed region at 126. The junction circuit 126 can facilitate interconnection of multiple photovoltaic cells 108 and/or strings 109 in a parallel or serial configuration. In various embodiments, the junction box 120 or junction circuit 126 can comprise a plurality of busbars or conductor ribbons electrically coupled to the solar cells 108 and/or solar cell strings 109. For example, the bus bars (not pictured) can penetrate the backsheet 105 of the laminate 106, pass through an opening 123 in the junction housing 122, and terminate within the junction box 120 at the junction circuit 126.

In some embodiments, the junction circuit 126 can include bypass diodes, which can provide an alternate current path through the module 100 should one of the solar cells 108 and/or solar cell strings 109 of the module 100 become damaged, shaded, or otherwise inoperable. In some embodiments, the junction box 120 comprises at least one bypass diode for protecting the solar cell cells 108 and/or strings 109 from reverse bias conditions. However, in other embodiments, bypass diodes may be absent.

As depicted in FIG. 4, the junction box 120 comprises a direct current (DC) output connector port 130 for outputting direct current generated by the solar cells 108. In an embodiment, the DC output connector 130 is electrically coupled to the junction circuit and/or busbars indicated at 126, for example through DC wires 128 depicted in FIG. 4. The DC wires 128 can be provided as two conductors (a plus and a minus) as depicted in FIG. 4, however other suitable arrangements can be provided. Either DC wire 128 can be grounded by connecting to the connected to the junction enclosure 122/124 (if grounded), the electronic component housing 142/144 (if grounded), or connected to another neutral or grounding conduit provided within the junction box 120.

The junction box 120 further comprises a conditioned power (e.g. AC power) input connector port 132 electrically coupled to the conditioned power (e.g. AC power) output link or cable 160 for outputting conditioned power (e.g. AC power) to an external load, for example through AC wires 138 depicted in FIG. 4. As depicted in FIG. 4, the AC wires 138 can be provided as three conductors (line 1, line 2, and ground). However other suitable arrangements can be provided, for example four conductors (line 1, line 2, neutral, and ground) can be provided. In various embodiments, the ground conductor can be electrically coupled to the electronic component enclosure 122/124.

In the exemplary embodiment depicted in FIG. 4, wires 138 directly connect the conditioned power input connector port 132 to the conditioned power output link, specifically a cable 160, for outputting conditioned power to an external load. However in other embodiments, the conditioned power input connector port 132 can be electrically coupled to a conditioned power output link provided as one or more electrical connectors or ports for transmitting conditioned power to an external load. In one example, the conditioned power input connector port 132 can be electrically coupled to a circuit board, or a linking circuit board, comprising surface mount connectors. The linking circuit board can in turn be coupled to one or more electrical connector ports for coupling to an external load. In such an embodiment, conditioned power can be transmitted from the conditioned power input connector port 132 to an external load via the linking circuit board and the one or more electrical connector ports.

The cross-sectional view of docking assembly 112 in FIG. 4 shows the electronic component 140 comprising an enclosure or housing 142 protecting and/or shielding power conditioning circuitry generally depicted at 146. The power conditioning circuitry 146 can comprise a printed circuit board (PCB) and electrical components. In one embodiment, the power conditioning circuitry 146 comprises a power inverter for converting direct current generated by the solar cells 108 to alternating current. An inverter topology may be constructed with multiple power stages, one of which may be an active filter converter. The power inverter may provide a single-phase or a three-phase output. In some embodiments, the electronic component housing 142 can enclose one or more power inverters at 146 or other power converter modules, such as DC-DC power optimizer or converter, which may be electrically coupled to the module 100 for various applications.

As depicted in FIG. 4, the electronic component 140 comprises a DC input connector port 150 configured to be electrically mated with the DC output connector port 130 of the junction box 120. The power conditioning circuitry 146 can be directly coupled to the DC input connector port 150 or through intervening conductors (not shown). The electronic component 140 further comprises a conditioned power output connector port 152 for outputting conditioned power from circuitry 146 and configured to be electrically mated with the conditioned power input connector port 132 of the junction box 120. The power conditioning circuitry 146 can be directly coupled to conditioned power output connector port 152 or through intervening conductors (not shown).

In embodiments where the electronic component 140 comprises a inverter circuitry at 146, the DC output connector 130 of the junction box 120 outputs direct current generated by the solar cells 108 through the DC input connector port 150 to the inverter circuitry and components at 146 for conversion to alternating current. The AC output connector port 152 is configured to be electrically mated with an AC input connector port 132 of the junction box 120 such that the alternating current produced by inverter 146 is transmitted to the junction box 120 through the AC output connector port 152 and the AC input connector port 132. The AC input connector port 132 of the junction box 120 is electrically coupled to an AC power output cable 160 for outputting AC power to an AC load, for example through AC wires 138 depicted in FIG. 4. In other words, the microinverter 140 converts direct current generated by the plurality of solar cells 108 to alternating current for delivery to an external AC load via the AC output cable 160 of the junction box 120.

In various embodiments, electronic component 140 comprises a potting material to fill voids between the housing 142/144 and interior electrical components including power conditioning circuitry 142 and connector ports 150/152. The potting material can be selected for optimal electrically insulating properties, thermal conductivity properties and/or prevention of moisture ingress.

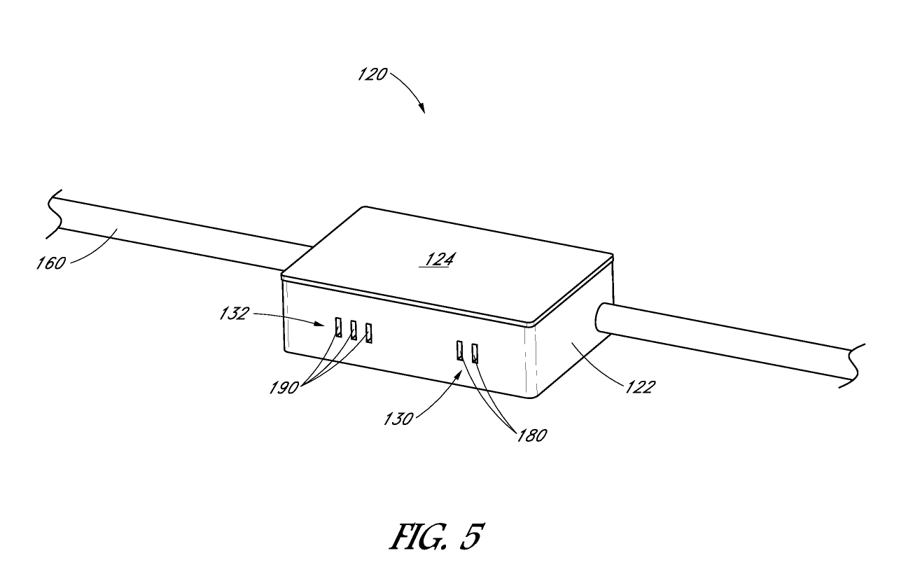

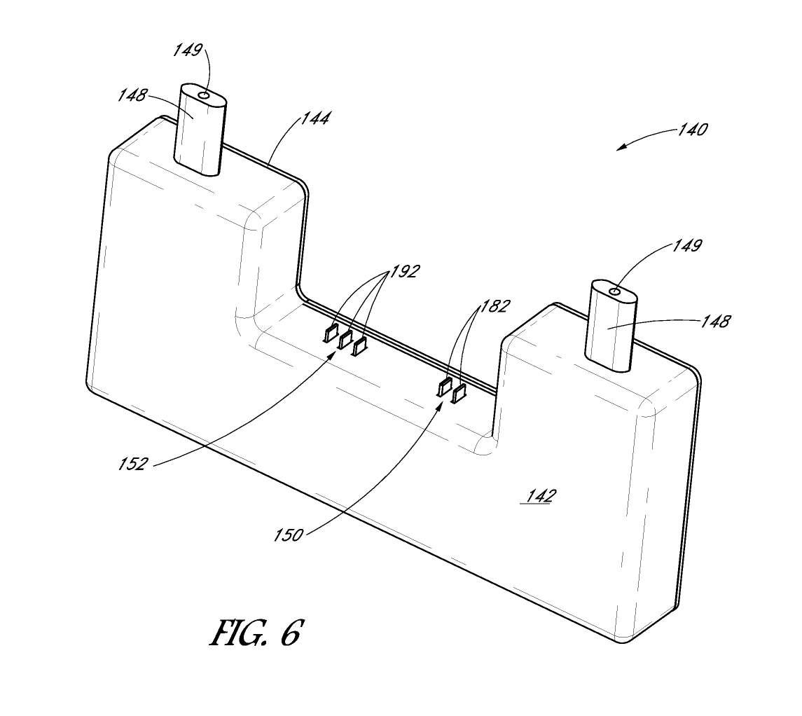

In an embodiment, the DC output connector port 130 of the junction box 120 is configured to be electrically mated with the DC input connector port 150 of the electronic component 140, for example via male and female spaded connectors. In the exemplary embodiment depicted in FIG. 5, the DC output connector port 130 of the junction box 120 comprises a plurality of sockets 180 which are electrically coupled to solar cells 108 through junction circuitry interior to the junction housing 122. As depicted in FIG. 6, the DC input connector port 150 of the electronic component 140 comprises a plurality of connector pins 182 configured to be electrically coupled to the power conditioning circuitry inside the electronic component housing 142. In an embodiment, each socket 180 of the DC output connector port 130 is configured to receive a corresponding connector pin 182 of the DC input connector port 150. Upon docking, sockets 180 receive connector pins 182, thereby electrically coupling the electronic component 140 to solar cells 108 via junction box 120.

In an embodiment, the power input connector port (e.g. AC input connector port) 132 of the junction box 120 is configured to be electrically mated with the conditioned power output connector port (e.g. AC output connector port) 152 of the electronic component (e.g. microinverter) 140, for example via male and female spaded connectors. Referring again to FIG. 5, the conditioned power input connector port 132 of the junction box 120 comprises a plurality of sockets 190 which are electrically coupled to the conditioned power output cable 160 via circuit internal to the junction housing 122/124. As depicted in FIG. 6, the conditioned power output connector port 152 of the electronic component 140 comprises a plurality of connector pins 192 configured to be electrically coupled to power conditioning circuitry (e.g. inverter circuitry) inside the electronic component housing 142/144. In an embodiment, each socket 190 of the conditioned power input connector port 132 is configured to receive a corresponding connector pin 192 of the conditioned power output connector port 152. Upon docking, sockets 190 receive connector pins 192, thereby electrically coupling the electronic component 140 to the junction box 120 such that conditioned power(e.g. AC power) is transmitted from the electrical component 140 to the conditioned power output cable 160 via junction box 120. In the exemplary embodiments depicted herein, electrical connection is achieved via sockets and corresponding connector pins, however any desired connector port features may be employed to electrically connect the electronic component 140 to the junction box 120. For example, male and female spade terminal connectors (e.g. manufactured by Molex), EXTreme PowerDock Connectors and/or any other similar connector.

In addition to being docked or coupled together electrically, the junction box 120 and the electrical component 140 can be coupled together mechanically through any desired coupling device or feature. For example, junction box 120 can be coupled to electronic component 142 by one or more fasteners, such as screws, bolts, rivets, snap-in features, compressible features, adhesives, or any other desirable mechanism for reversible coupling. In an embodiment, the particular coupling device, feature or mechanism is dictated by the ease of replacement or removal of the electronic component 140 from the junction box 120 and/or module 100.

In one embodiment, at least one gasket (e.g. a polymeric or rubber ring) is provided around connector ports of the docking assembly 112 to improve or create a seal for protection from moisture ingress. For example, a gasket can be provided around the DC output connector port 130, the DC input connector port 150, the power input connector port (e.g. AC input connector port) 132, the conditioned power output connector port (e.g. AC output connector port) 152, or a combination thereof.

In one embodiment, the electronic component 140 can comprise an engagement feature for mechanically coupling to a corresponding engagement feature of the junction box 120. For example, a connector port 152/152 of the electronic component 140 can comprise a guide post which interlocks with a cavity of a connector port 130/132 of the junction box 120. As another example, the electronic component 140 can comprise a compressible feature at one or more interfacial contact planes 170 such that upon docking with the junction box 120, the electronic component 140 and the junction box 120 are mechanically coupled or docked via compressive forces in a reversible manner.

In various embodiments, the junction box 120 and/or electronic component 140 is removably coupled to the frame 110 of module 100. In one embodiment, the junction box 120 and/or electronic component 140 is secured to the frame 110 of module 100 such that the junction box 120 and/or electronic component 140 is substantially centered between two corners of the frame 110 as depicted in FIG. 2. In other embodiments, the junction box 120 and/or electronic component 140 can be provided at or towards a corner of the frame 110.

In some embodiments, the module 100 will not include a frame. In such embodiments, the junction box 120 and/or electronic component 140 can be disposed substantially at the center or at a corner of the laminate 106. The junction box 120 and/or electronic component 140 can be coupled to the laminate 106 and/or frame 110 (if present) through any desired coupling device, feature or mechanism. For example, junction box 120 and/or electronic component 140 can be coupled to the laminate 106 and/or frame 110 (if present) by one or more adhesives, one or more fasteners, such as screws, bolts, rivets, snap-in features, compressible features or any other desirable mechanism for reversible or permanent coupling. In an embodiment, the electronic component 140 and/or the junction box 120 is electrically grounded to the frame 110 via a conductive feature of the docking assembly, either internal or external to the junction box 120 and/or electronic component 140.

In some embodiments, the configuration and mechanism for coupling the electronic component 142 to the laminate 106 and/or frame 110 (if present) is dictated by the desired spacing (e.g. for heat dissipation) between the electronic component 140 and the backsheet 105 of the laminate 106, for example to mitigate negative thermal effects relating to heat transfer from the electronic component 140 to the laminate 106. In some embodiments, the backsheet 105 and/or the electronic component 140 can comprise one or more guide features to maintain a desired configuration during docking.

In some embodiments, the electronic component 140 is reversibly mounted to the frame 110 of the module 100. The electronic component 140 can comprise mating features for mechanically coupling to a corresponding mating feature of the frame 110. For example as depicted in FIG. 2 and FIG. 6, the electronic component 140 comprises mounting arms 148 configured to be removably coupled to the frame 110 of the PV module 100. The mounting arms 148 of the electronic component 140 each include a cavity 149 configured to align with a corresponding feature e.g. opening of the frame 110 (not pictured). The mounting arms 148 of the electronic component 140 can be coupled to the frame 110 via one or more fasteners. For example, the cavity 149 can be threaded so as to accept a screw extending through an opening of the frame 100. The electronic component 140 can be mounted to the frame 110 and/or laminate 106 through any desired mounting device, feature or mechanism including but not limited to fasteners (e.g. screws, bolts, rivets, etc.), snap-in features, compressible features, adhesives, or any other desirable system for reversible or permanent mounting.

The above specification and examples provide a complete description of the structure and use of illustrative embodiments. Although certain embodiments have been described above with a certain degree of particularity, or with reference to one or more individual embodiments, those skilled in the art could make numerous alterations to the disclosed embodiments without departing from the scope of this invention. As such, the various illustrative embodiments of the methods and systems are not intended to be limited to the particular forms disclosed. Rather, they include all modifications and alternatives falling within the scope of the claims, and embodiments other than the one shown can include some or all of the features of the depicted embodiment. For example, elements can be omitted or combined as a unitary structure, and/or connections can be substituted. Further, where appropriate, aspects of any of the examples described above can be combined with aspects of any of the other examples described to form further examples having comparable or different properties and/or functions, and addressing the same or different problems. Similarly, it will be understood that the benefits and advantages described above can relate to one embodiment or can relate to several embodiments. For example, embodiments of the present methods and systems can be practiced and/or implemented using different structural configurations, materials, and/or control manufacturing steps. The claims are not intended to include, and should not be interpreted to include, means-plus- or step-plus-function limitations, unless such a limitation is explicitly recited in a given claim using the phrase(s) “means for” or “step for,” respectively.

1. An alternating current photovoltaic (ACPV) module comprising:
a photovoltaic (PV) laminate having a front side that faces the sun during normal operation to collect solar radiation during normal operation of the ACPV module and a back side opposite the from side, the PV laminate comprising:
a plurality of solar cells disposed within the PV laminate; the plurality of solar cells arranged into a plurality of solar cell strings; and,
a backsheet on the hack side of the PV laminate;
a frame surrounding the PV laminate;
a junction box coupled to the backsheet of the PV laminate for providing electrical access to the plurality of solar cell strings, the junction box comprising:
a plurality of busbars electrically coupled to the plurality of solar cell strings, each of the plurality of bus bars penetrating the backsheet of the PV laminate;
a direct current (DC) output connector port for outputting direct current generated by the plurality of solar cells strings, the DC output connector being electrically coupled to the plurality of busbars;
an alternating current (AC) input connector port; and,
an alternating current (AC) output cable;
a microinverter configured to be removably coupled to the junction box, the microinverter comprising:
a housing for protecting inverter circuitry;
a DC input connector port configured to be electrically mated with the DC output connector port of the junction box; and,
an AC output connector port configured to be electrically mated with the AC input connector port of the junction box;
wherein the microinverter converts direct current generated by the plurality of solar cells to alternating current for delivery to an external AC load via the AC output cable of the junction box.

2. The ACPV module according to claim 1, wherein the junction box comprises at least one bypass diode for protecting the plurality of solar cell strings from reverse bias conditions.

3. The ACPV module according to claim 1, wherein the inverter housing is removably coupled to the frame.

4. The ACPV module according to claim 3, wherein the inverter housing is secured to the frame of the ACPV module toward a corner of the frame.

5. The ACPV module according to claim 3, wherein the inverter housing is secured to the frame of the ACPV module so that the inverter housing is centered between two corners of the frame.

6. A photovoltaic docking assembly comprising:
a junction housing for providing electrical access to a plurality of solar cells, the junction housing comprising:
a plurality of busbars electrically coupled to the plurality of solar cells;
a DC output connector port for outputting direct current generated by the plurality of solar cells;
a conditioned power input connector port; and,
a conditioned power output link for outputting conditioned power to an external load;
an electronic component configured to be removably coupled to the junction housing, the electronic component comprising:
a housing protecting the electronic component for conditioning power generated by the plurality of solar cells;
a DC input connector port configured to be electrically mated with the DC output connector port of the junction housing; and,
a conditioned power output connector port configured to be electrically mated with the power input connector port of the junction housing.

7. The photovoltaic docking assembly according to claim 6, wherein the electronic component comprises a microinverter for converting direct current generated by the plurality of solar cells into alternating current and outputting alternating current to the conditioned power output connector port of the electronic component housing.

8. The photovoltaic docking assembly according to claim 6, wherein the electronic component comprises an electronic DC to DC optimizer.

9. The photovoltaic docking assembly according to claim 6, wherein the junction housing comprises at least one bypass diode.

10. The photovoltaic docking assembly according to claim 6, wherein the electronic component housing at least partially surrounds the junction housing.

11. The photovoltaic docking assembly according to claim 6, wherein the PV module includes a frame, and the electronic component housing is mounted to the frame of the PV module.

12. The photovoltaic docking assembly according to claim 11, wherein the electronic component housing comprises at least one mating feature for mechanically coupling to a corresponding mating feature of the frame.

13. The photovoltaic docking assembly according to claim 11, wherein the electronic component housing comprises at least one mounting arm configured to be removably coupled to the frame of the PV module.

14. The photovoltaic docking assembly according to claim 13, wherein the at least one mounting arm includes a cavity configured to align with a corresponding opening of the frame; and, wherein the docking system further comprises at least one fastener configured to be disposed through a respective aligned cavity of the at least one mounting arm and the corresponding opening of the frame.

15. The photovoltaic docking assembly according to claim 6, wherein the DC output connector port of the junction housing comprises a plurality of sockets configured to be electrically coupled to the plurality of solar cells; the DC input connector port of the electronic component housing comprises a plurality of connector pins configured to be electrically coupled to the electronic component;
wherein each of the plurality of sockets of the DC output connector port is configured to receive one of the plurality of connector pins of the DC input connector port; and,
wherein receipt of the plurality of connector pins by the plurality of sockets electrically couples the electronic component to the plurality of solar cells.

16. The photovoltaic docking assembly according to claim 6, wherein the conditioned power input connector port of the junction housing comprises a plurality of sockets configured to be electrically coupled to the conditioned power output link; the conditioned power output connector port of the electronic component housing comprises a plurality of connector pins configured to be electrically coupled to the electronic component;
wherein each of the plurality of sockets of the conditioned power input connector port is configured to receive one of the plurality of connector pins of the conditioned power output connector port; and,
wherein receipt of the plurality of connector pins by the plurality of sockets electrically couples the electronic component to the conditioned power output link.

17. The photovoltaic docking assembly according to claim 6, wherein a connector port of the electronic component housing comprises an engagement feature for mechanically coupling to a corresponding engagement feature of a connector port of the junction housing.

18. The photovoltaic docking assembly according to claim 17, wherein the engagement feature comprises an interlocking guide post and cavity.

19. A junction box for or electrically coupling a photovoltaic module to a microinverter, the junction box comprising:
a plurality of busbars electrically coupled to a plurality of solar cells of the photovoltaic module;
a DC output connector for outputting direct current generated by the photovoltaic module to the microinverter for conversion to alternating current;
an AC power input connector port for inputting alternating current produced by the microinverter; and,
an AC power output link for outputting AC power to an AC load.

20. The junction box according to claim 19, wherein the junction housing comprises at least one bypass diode.
